(19) United States
(12) Patent Application Publication
(10) Pub. No.: US 2021/0141000 A1
(43) Pub. Date: May 13, 2021

(54) PROBE PIN CLEANING PAD AND CLEANING METHOD FOR PROBE PIN

(71) Applicant: Alliance Material Co., Ltd., Hsinchu County (TW)

(72) Inventors: Chun-Fa Chen, Hsinchu County (TW); Chi-Hua Huang, Hsinchu County (TW); Yu-Hsuen Lee, Hsinchu County (TW); Chen-Ju Lee, Hsinchu County (TW); Huan-Hsuan Ku, Hsinchu County (TW); Ching-Wen Hsu, Hsinchu County (TW); Chin-Kai Lin, Hsinchu County (TW)

(73) Assignee: Alliance Material Co., Ltd., Hsinchu County (TW)

(21) Appl. No.: 17/095,747

(22) Filed: Nov. 12, 2020

Related U.S. Application Data
(60) Provisional application No. 62/933,990, filed on Nov. 12, 2019.

(30) Foreign Application Priority Data
Mar. 2, 2020 (TW) 109106766
Oct. 22, 2020 (TW) 109136656

(51) Int. Cl. G01R 3/00; B08B 1/00; G01R 1/067

(52) U.S. Cl. CPC G01R 3/00; G01R 1/067; B08B 1/006

(57) ABSTRACT

A probe pin cleaning pad is provided, including a release layer or composite plate, an adhesive layer, a substrate layer, and a cleaning layer. The adhesive layer is disposed on the release layer or composite plate. The substrate layer is disposed on the adhesive layer. The cleaning layer is disposed on the substrate layer. A cleaning method for a probe pin is also provided.

### CROSS-REFERENCE TO RELATED APPLICATION

This application claims the priority benefits of U.S. provisional application Ser. No. 62/933,990, filed on Nov. 12, 2019, Taiwan application serial no. 109106766, filed on Mar. 2, 2020 and Taiwan application serial no. 109136656, filed on Oct. 22, 2020. The entirety of each of the above-mentioned patent applications is hereby incorporated by reference herein and made a part of this specification.

### BACKGROUND

### Technical Field

The disclosure relates to a cleaning pad and a cleaning method for a probe pin, particularly to a probe pin cleaning pad and a cleaning method for a probe pin by using the probe pin cleaning pad.

### Description of Related Art

In a test (for example but not limited to, final test (FT) or chip probing (CP)) of an electronic component, a probe pin is often employed for electrical measurement. Impurities or scratches, if any, present on the probe pin, may affect test results of the electronic component.

### SUMMARY

The disclosure provides a probe pin cleaning pad and a cleaning method for a probe pin by using the probe pin cleaning pad, which are suitable for cleaning of probe pins.

A probe pin cleaning pad according to the disclosure includes a release layer or composite material, an adhesive layer, a substrate layer, and a cleaning layer. The adhesive layer is disposed on the release layer or composite material. The substrate layer is disposed on the adhesive layer. The cleaning layer is disposed on the substrate layer.

In an embodiment of the disclosure, the release layer or composite material, the adhesive layer, the substrate layer, and the cleaning layer are sequentially stacked.

In an embodiment of the disclosure, the adhesive layer has a thickness of greater than or equal to 5 μm and less than or equal to 100 μm.

In an embodiment of the disclosure, the substrate layer has a thickness of greater than or equal to 6 μm and less than or equal to 300 μm.

In an embodiment of the disclosure, the cleaning layer has a Mohs hardness of less than 7, or has a Young's modulus of less than or equal to 100 kg/cm².

In an embodiment of the disclosure, the cleaning layer has a thickness of greater than or equal to 50 μm and less than or equal to 500 μm.

In an embodiment of the disclosure, a material of the cleaning layer includes resin and organic powders.

In an embodiment of the disclosure, the resin includes silicone, polyurethane, or a combination of the foregoing.

In an embodiment of the disclosure, the organic powders have a hardness of less than or equal to 7.

In an embodiment of the disclosure, a material of the cleaning layer includes an organic material.

A cleaning method for a probe pin according to the disclosure includes the following. In step 1, an electronic component is tested by the probe pin. In step 2, after step 1, the probe pin is cleaned by the probe pin cleaning pad of any one of the foregoing embodiments.

In an embodiment of the disclosure, step 1 and step 2 are performed in-situ or on-line.

Based on the above, in the probe pin cleaning pad and the cleaning method for a probe pin by using the probe pin cleaning pad according to the disclosure, since the cleaning layer is adapted to adhere to and cover a substance on the probe pin, the probe pin cleaning pad and the cleaning method for a probe pin are suitable for cleaning of probe pins and may reduce scratches on the probe pins.

### BRIEF DESCRIPTION OF THE DRAWINGS

FIG. 1 is a schematic cross-sectional view of a probe pin cleaning pad according to a first embodiment of the disclosure.

FIG. 2 is a schematic cross-sectional view of a probe pin cleaning pad according to a second embodiment of the disclosure.

FIG. 3A to FIG. 3F are schematic views of a cleaning method for a probe pin according to an embodiment of the disclosure.

FIG. 4A and FIG. 4B are schematic enlarged partial cross-sectional views of a cleaning method for a probe pin according to an embodiment of the disclosure.

FIG. 5A and FIG. 5B are enlarged partial views of a surface of a probe pin after cleaning according to Experimental Example 1 and Comparative Example 1.

FIG. 6A and FIG. 6B are enlarged partial cross-sectional views of a probe pin cleaning pad after use according to Experimental Example 2 and Comparative Example 2.

FIG. 7A and FIG. 7B are enlarged partial views of a probe pin cleaning pad after use according to Comparative Example 3.

FIG. 8A and FIG. 8B are enlarged partial views of a probe pin cleaning pad after use according to Experimental Example 3.

### DESCRIPTION OF THE EMBODIMENTS

In the drawings, sizes of elements or layers may be enlarged or reduced for clarity. In addition, some layers or components may be omitted from the drawings for clarity.

Directional terms (for example, up, down, right, left, front, back, top, and bottom) as used herein are made only with reference to the figures as drawn and are not intended to imply absolute orientation.

A numerical value indicated in the specification may include the numerical value and a deviation value within a range acceptable to one of ordinary skill in the art. The above deviation value may be one or more standard deviations in a manufacturing or measurement process, or calculation error caused by factors such as the number of digits used in calculation or conversion, rounding, or error propagation.

FIG. 1 is a schematic cross-sectional view of a probe pin cleaning pad according to a first embodiment of the disclosure.

Referring to FIG. 1, a probe pin cleaning pad 100 may include a release layer 110, an adhesive layer 120, a substrate layer 130, and a cleaning layer 140. The release layer 110 is located under the adhesive layer 120 (in a lower part of FIG. 1). The adhesive layer 120 is located under the substrate layer 130 (in the lower part of FIG. 1). The cleaning layer 140 is located on the substrate layer 130 (in an upper part of FIG. 1). That is, the adhesive layer 120 and the cleaning layer 140 are respectively located on two opposite sides of the substrate layer 130.

In the present embodiment, the probe pin cleaning pad 100 may include the release layer 110, the adhesive layer 120, the substrate layer 130 and the cleaning layer 140 that are disposed in a stacked manner. For example, two opposite surfaces of the adhesive layer 120 may directly contact the release layer 110 and the substrate layer 130, and two opposite surfaces of the substrate layer 130 may directly contact the adhesive layer 120 and the cleaning layer 140.

In the present embodiment, the release layer 110 may include a release film or release paper. However, the disclosure is not limited thereto. In one embodiment, a material of the release film serving as the release layer 110 may include polyethylene terephthalate (PET). In one embodiment, the release film may have a thickness of 25 micrometers (μm) to 175 μm. However, the disclosure is not limited thereto. In one embodiment, the release film may have a release force of 2 gf/25 mm to 200 gf/25 mm. However, the disclosure is not limited thereto.

In the present embodiment, the adhesive layer 120 has a thickness of greater than or equal to 5 μm and less than or equal to 100 μm. For example, the adhesive layer 120 basically has a thickness of 25 μm.

If the adhesive layer 120 has a thickness of less than 5 μm, adhesion force of the adhesive layer 120 may be reduced.

If the adhesive layer 120 has a thickness of greater than 100 μm, the overall thickness of the probe pin cleaning pad 100 may be increased due to the excessive thickness of the adhesive layer 120, thus increasing the material cost or affecting the use of the other layers.

In the present embodiment, the substrate layer 130 has a thickness of greater than or equal to 6 μm and less than or equal to 300 μm. For example, the substrate layer 130 basically has a thickness of 100 μm.

If the substrate layer 130 has a thickness of less than 6 μm, insufficient support is provided. Moreover, or alternatively, an object to be cleaned (for example, a probe pin 91 in FIG. 3C, FIG. 3F, FIG. 4A or FIG. 4B) may pierce the substrate layer 130.

If the substrate layer 130 has a thickness of greater than 300 μm, the overall thickness of the probe pin cleaning pad 100 may be increased, thus increasing the material cost or affecting the other layers.

In the present embodiment, the cleaning layer 140 has a Mohs hardness of less than 7. If the cleaning layer 140 has a Mohs hardness of greater than 7, scratches may be caused on the object to be cleaned (for example, the probe pin 91 in FIG. 3C, FIG. 3F, FIG. 4A or FIG. 4B).

In one embodiment, if the cleaning layer 140 has a Mohs hardness of 4 to 7, peeling or removal of impurities from the object to be cleaned (for example, the probe pin 91 in FIG. 3C, FIG. 3F, FIG. 4A or FIG. 4B) may be facilitated.

In the present embodiment, the cleaning layer 140 has a Young's modulus of less than or equal to 100 kg/cm². If the cleaning layer 140 has a Young's modulus of greater than 100 kg/cm², when the object to be cleaned (for example, the probe pin 91 in FIG. 3C, FIG. 3F, FIG. 4A or FIG. 4B) and the probe pin cleaning pad 100 contact each other, the cleaning ability of the cleaning layer 140 may be reduced.

In one embodiment, the cleaning layer 140 has a Young's modulus of greater than or equal to 30 kg/cm². If the cleaning layer 140 has a Young's modulus of less than 30 kg/cm², the cleaning ability of the cleaning layer 140 may be reduced.

In one embodiment, the cleaning layer 140 may have a Young's modulus of greater than or equal to 30 kg/cm² and less than or equal to 100 kg/cm².

In one embodiment, the cleaning layer 140 may further have a Young's modulus of less than or equal to 70 kg/cm². In one embodiment, the cleaning layer 140 may have a Young's modulus of greater than or equal to 30 kg/cm² and less than or equal to 70 kg/cm².

In one embodiment, the cleaning layer 140 may further have a Young's modulus of greater than or equal to 50 kg/cm². In one embodiment, the cleaning layer 140 may have a Young's modulus of greater than or equal to 50 kg/cm² and less than or equal to 100 kg/cm².

In one embodiment, the cleaning layer 140 may further have a Young's modulus of greater than or equal to 50 kg/cm² and less than or equal to 70 kg/cm². When the object to be cleaned (for example, the probe pin 91 in FIG. 3C, FIG. 3F, FIG. 4A or FIG. 4B) and the probe pin cleaning pad 100 contact each other, the cleaning ability and the number of uses of the cleaning layer 140 may further be improved.

In one embodiment, the cleaning layer 140 may have a Mohs hardness of less than 7, and may have a Young's modulus of less than or equal to 100 kg/cm², or further less than or equal to 70 kg/cm².

In one embodiment, the cleaning layer 140 may have a Mohs hardness of less than 7, and may have a Young's modulus of greater than or equal to 30 kg/cm², or further greater than or equal to 50 kg/cm².

In one embodiment, the cleaning layer 140 has a Mohs hardness of less than 7. Moreover, the cleaning layer 140 may have a Young's modulus of greater than or equal to 30 kg/cm² and less than or equal to 100 kg/cm².

In one embodiment, the cleaning layer 140 has a Mohs hardness of less than 7. Moreover, the cleaning layer 140 may have a Young's modulus of greater than or equal to 30 kg/cm² and less than or equal to 70 kg/cm².

In one embodiment, the cleaning layer 140 has a Mohs hardness of less than 7. Moreover, the cleaning layer 140 may have a Young's modulus of greater than or equal to 50 kg/cm² and less than or equal to 100 kg/cm².

In one embodiment, the cleaning layer 140 has a Mohs hardness of less than 7. Moreover, the cleaning layer 140 may have a Young's modulus of greater than or equal to 70 kg/cm² and less than or equal to 70 kg/cm². When the object to be cleaned (for example, the probe pin 91 in FIG. 3C, FIG. 3F, FIG. 4A or FIG. 4B) and the probe pin cleaning pad 100 contact each other, the cleaning ability and the number of uses of the cleaning layer 140 may further be improved, and the risk of wear (for example, the occurrence of scratches) of the object to be cleaned (for example, the probe pin 91 in FIG. 3C, FIG. 3F, FIG. 4A or FIG. 4B) may be reduced.

In the present embodiment, a material of the substrate layer 130 may include polyethylene terephthalate (PET), polyimide (PI), or a stack of the foregoing or a combination of the foregoing. However, the disclosure is not limited thereto.

In the present embodiment, a material of the cleaning layer 140 includes resin and organic powders.

In one embodiment, the resin constituting the cleaning layer 140 may include silicone resin, polyurethane (PU) resin, acrylic resin, or a combination of the foregoing. However, the disclosure is not limited thereto.

In one embodiment, the organic powders may be adapted to be adhered or bonded to a metal material (for example, solder).

In one embodiment, the organic powders may include a nitrogen-containing aromatic heterocyclic compound, an aliphatic amine compound, or a combination of the foregoing. However, the disclosure is not limited thereto.

In one embodiment, the nitrogen-containing aromatic heterocyclic compound includes, for example, pyrazole, imidazole, triazole, benz-pyrazole, benzimidazole, benzotriazole, purine, imidazo[4,5-b]pyridine, a compound similar to the foregoing (for example, the foregoing compounds in which one of hydrogens is replaced by halogen, C1-C6 alkyl group, or other suitable substituent), or a combination of the foregoing compounds.

In one embodiment, the aliphatic amine compound may include at least one of a primary amine, a secondary amine, and a tertiary amine. Examples of the primary amine include at least one of aminoethane, 1-aminopropane, 2-aminopropane, 1-aminobutane, 2-aminobutane, 1-amino-2-methylpropane, 2-amino-2-methylpropane, 1-aminopentane, 2-aminopentane, 3-aminopentane, neopentylamine, 1-aminohexane, 1-aminoheptane, 2-aminoheptane, 1-aminooctane, 2-aminooctane, 1-aminononane, 1-aminodecane, 1-aminododecane, 1-aminotridecane, 1-aminotetradecane, 1-aminopentadecane, 1-aminohexadecane, 1-aminoheptadecane, and 1-aminooctadecane. Examples of the secondary amine include at least one of diethylamine, dipropylamine, dibutylamine, dipentylamine, dihexylamine, diheptylamine, dioctylamine, dinonylamine, didecylamine, diundecylamine, didodecylamine, ditridecylamine, ditetradecylamine, dipentadecylamine, dihexadecylamine, diheptadecanamine, and dioctadecylamine. Examples of the tertiary amine include at least one of triethylamine, tripropylamine, tributylamine, tripentylamine, trihexylamine, triheptylamine, trioctylamine, trinonylamine, tridecylamine, triundecylamine, tridodecylamine, tritridecylamine, tritetradecylamine, tripentadecylamine, trihexadecylamine, triheptadecamine, and trioctadecylamine. In one embodiment, the aliphatic amine compound may include one or more amino groups.

In one embodiment, the organic powders may further be adapted to be adhered or bonded to organopolysiloxane, polyurethane or acrylic resin. For example, a compound constituting the organic powders may further include at least one of alkenyl group, ether group, amide group, amino group, carboxyl group, ester group, alcohol group, silyl group, alkoxy group, and alkoxysilyl group.

In one embodiment, the organic powders have a Mohs hardness of less than 7. If the organic powders have a Mohs hardness of greater than 7, scratches may be caused on the object to be cleaned (for example, the probe pin 91 in FIG. 3C, FIG. 3F, FIG. 4A or FIG. 4B).

In one embodiment, a material of the cleaning layer 140 includes an organic material. That is, the material of the cleaning layer 140 may include no inorganic material.

In the present embodiment, the cleaning layer 140 has a thickness of greater than or equal to 50 μm and less than or equal to 500 μm. If the cleaning layer 140 has a thickness of less than 50 μm, the cleaning ability of the probe pin cleaning pad 100 may be reduced. If the cleaning layer 140 has a thickness of greater than 500 μm, the risk of peeling of the cleaning layer 140 itself may be increased.

In one embodiment, the cleaning layer 140 has a thickness of greater than or equal to 100 μm and less than or equal to 300 μm. For example, in the present embodiment, the cleaning layer 140 may basically have a thickness of 225 μm.

In the present embodiment, the probe pin cleaning pad 100 may serve as a probe card cleaning pad. However, the disclosure is not limited thereto.

FIG. 2 is a schematic cross-sectional view of a probe pin cleaning pad according to a second embodiment of the disclosure.

Referring to FIG. 2, a probe pin cleaning pad 200 may include a composite material 210, an adhesive layer 220, a substrate layer 230, and a cleaning layer 240. The adhesive layer 220 is located under the composite material 210 (in a lower part of FIG. 2). The substrate layer 230 is located under the adhesive layer 220 (in the lower part of FIG. 2). The cleaning layer 240 is located under the substrate layer 230 (in the lower part of FIG. 2).

In the present embodiment, the probe pin cleaning pad 200 may include the composite material 210, the adhesive layer 220, the substrate layer 230 and the cleaning layer 240 that are disposed in a stacked manner. For example, two opposite surfaces of the adhesive layer 220 may directly contact the composite material 210 and the substrate layer 230, and two opposite surfaces of the substrate layer 230 may directly contact the adhesive layer 220 and the cleaning layer 240.

In the present embodiment, the composite material 210 may include a rigid plate-shaped body. However, the disclosure is not limited thereto. In one embodiment, a material of the rigid plate-shaped body serving as the composite material 210 may include a silicon substrate, a glass fiber board (for example, FR4 board), a rigid plastic substrate (for example, acrylic sheet), or a composite plate of the foregoing. In one embodiment, the composite plate may have a thickness of 100 μm to 2000 μm. However, the disclosure is not limited thereto. For example, the composite plate basically has a thickness of 750 μm.

In the present embodiment, a material of the substrate layer 230 of the probe pin cleaning pad 200 may be the same as or similar to the material of the substrate layer 130 of the foregoing embodiments, and both elements have the same or similar uses or properties. Therefore, a detailed description will be omitted.

In the present embodiment, a material of the cleaning layer 240 of the probe pin cleaning pad 200 may be the same as or similar to the material of the cleaning layer 140 of the foregoing embodiments, and both elements have the same or similar uses or properties. Therefore, a detailed description will be omitted.

In the present embodiment, the cleaning layer 240 may basically have a thickness of 150 μm.

In the present embodiment, the probe pin cleaning pad 200 may serve as a test socket cleaning pad. However, the disclosure is not limited thereto.

In the disclosure, a probe pin may be cleaned by the probe pin cleaning pad 100 or 200 of any one of the foregoing embodiments. It is worth noting that the disclosure does not limit the use of the probe pin cleaning pad 100 or 200 of any one of the foregoing embodiments.

A cleaning method for a probe pin may include the following steps. In step 1, an electronic component is tested by the probe pin. In step 2, after step 1, the probe pin is cleaned by the probe pin cleaning pad 100 or 200 of any one of the foregoing embodiments.

The cleaning method for a probe pin is exemplified as follows. Referring to FIG. 3A to FIG. 4B, FIG. 3A to FIG. 3F are schematic views of a cleaning method for a probe pin according to an embodiment of the disclosure, and FIG. 4A and FIG. 4B are schematic enlarged partial cross-sectional views of a cleaning method for a probe pin according to an embodiment of the disclosure.

Referring to FIG. 3A to FIG. 3C, an electronic component 70 may be electrically tested by a common test method using the probe pin 91.

As an example, in FIG. 3A, the electronic component 70 and a probe pin cleaning pad 300 are provided.

In the present embodiment, the electronic component 70 is, for example, a bare die or a chip package. However, the disclosure is not limited thereto.

In the present embodiment, the probe pin cleaning pad 300 may be the same as or similar to the probe pin cleaning pad 200 of the foregoing embodiments. That is, a material of a substrate layer 330 of the probe pin cleaning pad 300 may be the same as or similar to the material of the substrate layer 230 of the foregoing embodiments, and both elements have the same or similar uses or properties. Therefore, a detailed description will be omitted. Alternatively, a material of a cleaning layer 340 of the probe pin cleaning pad 300 may be the same as or similar to the material of the cleaning layer 240 of the foregoing embodiments, and both elements have the same or similar uses or properties (for example, Mohs hardness). Therefore, a detailed description will be omitted. In addition, an adhesive layer (which is, for example, the same as or similar to the adhesive layer 240) and a composite material (which is, for example, the same as or similar to the composite material 210) of the probe pin cleaning pad 300 are omitted from illustration in the drawings.

In one embodiment (not shown), the probe pin cleaning pad 300 may be the same as or similar to the probe pin cleaning pad 100 of the foregoing embodiments.

Then, as shown in FIG. 3B, the electronic component 70 to be tested may be picked up by a pick-up head 81 of a pick-up-and-place device 80.

Then, as shown in FIG. 3C, by the pick-up-and-place device 80, the electronic component 70 to be tested may be placed on a test device 90.

The test device 90 has, for example, multiple probe pins 91. The probe pin 91 may contact a conductive terminal (for example, solder ball) (not shown) or a contact pad (not shown) on a surface under test 71 of the electronic component 70, so as to test the electronic component 70. For example, pressure may be applied to the electronic component 70 to be tested and/or the probe pin 91, so that the conductive terminal or contact pad on the surface under test 71 of the electronic component 70 to be tested and the probe pin 91 contact each other.

In one embodiment, during the contact between the electronic component 70 and the probe pin 91, some substances (for example, a solder that forms the conductive terminal, or an aluminum material, zinc material, copper material, carbon material or eutectic composition that forms the contact pad) may be attached to the probe pin 91.

In the present embodiment, the test method is, for example, final test (FT). However, the disclosure is not limited thereto. In one embodiment, the test method may be chip probing (CP).

After the exemplary test shown in FIG. 3A to FIG. 3C, the probe pin 91 may be cleaned by the probe pin cleaning pad 300 in a similar operation manner.

Taking FIG. 3C to FIG. 3D as an example, after the electronic component 70 is tested, the electronic component 70 and the probe pin 91 may be separated from each other, and the electronic component 70 may be placed by the pick-up-and-place device 80.

In one embodiment, during the separation of the electronic component 70 and the probe pin 91, some substances (for example, a solder that forms the conductive terminal, or an aluminum material, zinc material, copper material, carbon material or eutectic composition that forms the contact pad) may peel off and be attached to the probe pin 91.

Then, as shown in FIG. 3E, the probe pin cleaning pad 300 may be picked up by the pick-up head 81 of the pick-up-and-place device 80.

Then, as shown in FIG. 3F, by the pick-up-and-place device 80, the probe pin cleaning pad 300 may be placed on the test device 90, so that the probe pin 91 can be cleaned by the probe pin cleaning pad 300.

For example, pressure may be applied to the probe pin cleaning pad 300 and/or the probe pin 91, so that the probe pin cleaning pad 300 and the probe pin 91 contact each other, causing a substance 99 (which is, for example, a solder, an aluminum material, a zinc material, a copper material, a carbon material or eutectic composition; marked or shown in FIG. 4A or FIG. 4B) attached to the probe pin 91 to adhere to the cleaning layer 340 of the probe pin cleaning pad 300. After that, the probe pin cleaning pad 300 and the probe pin 91 may be separated from each other, and the substance 99 attached to the probe pin 91 may be reduced by the probe pin cleaning pad 300.

For details, please refer to FIG. 4A and FIG. 4B. As shown in FIG. 4A, one end (that is, one end for contacting the electronic component 70) of the probe pin 91 for testing pierces at least the cleaning layer 340 of the probe pin cleaning pad 300. Then, as shown in FIG. 4B, after the probe pin cleaning pad 300 and the probe pin 91 are separated from each other, the amount of the substance 99 attached to and/or coated on the probe pin 91 can be reduced.

In the method or step for cleaning the probe pin 91 by the probe pin cleaning pad 100, 200 or 300 of any one of the foregoing embodiments of the disclosure, the probe pin 91 may not be disassembled or separated from the test device 90. Moreover, the cleaning of the probe pin 91 may be performed under the same or similar recipe for testing the electronic component 70. That is, the steps of the method for cleaning the probe pin 91 may be performed in-situ or on-line.

It is worth noting that, FIG. 3A to FIG. 4B only exemplarily describe one method for cleaning the probe pin 91, and the type of the probe pin 91 is not limited in the disclosure. For example, in FIG. 3A to FIG. 4B, the probe pin 91 as shown is a vertical probe pin. However, the disclosure is not limited thereto. In one embodiment (not shown), the probe pin cleaning pad 100, 200 or 300 of any one of the foregoing embodiments of the disclosure may be employed for cleaning of a cantilever probe pin by a similar common test method.

### EXPERIMENTAL EXAMPLES AND COMPARATIVE EXAMPLES

The disclosure will be specifically described by way of experimental examples and comparative examples shown below. The embodiments of the disclosure may include, but are not limited to, the following experimental examples. In addition, in the later-described comparative examples, the description “a cleaning layer-like layer” may refer to a layer different from the cleaning layer of the disclosure. For example, the “cleaning layer-like layer” may be of a different composition from that of the cleaning layer of the disclosure. For example, the “cleaning layer-like layer” may be of a composition partially the same as that of the cleaning layer of the disclosure. However, the “cleaning layer-like layer” may be different from the cleaning layer of the disclosure in terms of thickness, Mohs hardness and/or Young's modulus.

### Experimental Example 1 and Comparative Example 1

In Experimental Example 1 and Comparative Example 1, a probe pin was cleaned by the same cleaning method. A difference is that Experimental Example 1 employed the probe pin cleaning pad of the disclosure, while Comparative Example 1 did not employ the probe pin cleaning pad of the disclosure. Moreover, the probe pin cleaning pad employed in Comparative Example 1 was similar to the probe pin cleaning pad employed in Experimental Example 1, and a difference is that a cleaning layer-like layer (which, however, was not the cleaning layer of the disclosure) in Comparative Example 1 was of a different composition from that of the cleaning layer of the disclosure.

As shown in Table 1, FIG. 5A and FIG. 5B, after the probe pin was cleaned by the probe pin cleaning pad of Experimental Example 1 and the probe pin cleaning pad of Comparative Example 1, surface flatness of the probe pin cleaning pad was evaluated. FIG. 5A is an enlarged partial view of a surface of the probe pin cleaning pad after the probe pin was cleaned by the probe pin cleaning pad of Experimental Example 1. FIG. 5B is an enlarged partial view of a surface of the probe pin cleaning pad after the probe pin was cleaned by the probe pin cleaning pad of Comparative Example 1. Moreover, FIG. 5A and FIG. 5B have the same or similar image capturing conditions (for example, magnifying power and/or electron beam energy of an electron microscope). In Table 1, symbol “O” indicates that the result was at least in line with expectations or exceeded expectations, and symbol “X” indicates that the result at least did not meet expectations or was unacceptable.

TABLE 1

| | Experiment | Comparative |
|---|---|---|
| | Example 1 | Example 1 |
| Surface flatness of probe pin cleaning pad | ◯ | X |

As shown in Table 1, FIG. 5A and FIG. 5B, compared to Comparative Example 1, the probe pin cleaning pad after the probe pin was cleaned by the probe pin cleaning pad of Experimental Example 1 exhibited better surface flatness. That is, the probe pin after cleaning by the probe pin cleaning pad of Experimental Example 1 may have fewer scratches and/or fewer impurities thereon.

### Experimental Example 2 and Comparative Example 2

In Experimental Example 2 and Comparative Example 2, a probe pin was cleaned by the same cleaning method. A difference is that Experimental Example 2 employed the probe pin cleaning pad of the disclosure, while Comparative Example 2 did not employ the probe pin cleaning pad of the disclosure. Moreover, the probe pin cleaning pad employed in Comparative Example 2 was similar to the probe pin cleaning pad employed in Experimental Example 2, and a difference is that a cleaning layer-like layer (which, however, was not the cleaning layer of the disclosure) in Comparative Example 2 was of a different composition from that of the cleaning layer of the disclosure.

As shown in Table 2, FIG. 6A and FIG. 6B, after the probe pin was cleaned by the probe pin cleaning pad of Experimental Example 2 and the probe pin cleaning pad of Comparative Example 2, impurity adhesion ability of the probe pin cleaning pads was evaluated. FIG. 6A is an enlarged partial cross-sectional view of the probe pin cleaning pad of Experimental Example 2 after use. FIG. 6B is enlarged partial cross-sectional view of the probe pin cleaning pad of Comparative Example 2 after use. Moreover, FIG. 6A and FIG. 6B have the same or similar image capturing conditions (for example, magnifying power and/or electron beam energy of an electron microscope). In Table 2, symbol “0” indicates that the result was at least in line with expectations or exceeded expectations, and symbol “X” indicates that the result at least did not meet expectations or was unacceptable.

TABLE 2

| | Experiment | Comparative |
|---|---|---|
| | Example 2 | Example 2 |
| Elasticity or adhesion | ◯ | X |

As shown in Table 2, FIG. 6A and FIG. 6B, compared to Comparative Example 2, the cleaning layer of the probe pin cleaning pad of Experimental Example 2 exhibited better elasticity or adhesion. Thus, after the probe pin cleaning pad and the probe pin were separated from each other, punctures caused in the cleaning layer of the probe pin cleaning pad of Experimental Example 2 were relatively small due to the better elasticity or adhesion of the cleaning layer.

### Experimental Example 3 and Comparative Example 3

In Experimental Example 3 and Comparative Example 3, a commercially available four jaw probe pin (a type of vertical probe pin) was cleaned by the same cleaning method (for example, the same puncturing method). A difference is that Experimental Example 3 employed the probe pin cleaning pad of the disclosure, while Comparative Example 3 did not employ the probe pin cleaning pad of the disclosure. The probe pin cleaning pad employed in Comparative Example 3 was similar to the probe pin cleaning pad employed in Experimental Example 3, and a difference is that a cleaning layer-like layer (which, however, was not the cleaning layer of the disclosure) in Comparative Example 3 had a Young's modulus of less than 30 kg/cm². Specifically, the cleaning layer of the probe pin cleaning pad employed in Experimental Example 3 had a Young's modulus of greater than or equal to 50 kg/cm² and less than or equal to 70 kg/cm².

As shown in FIG. 7A, FIG. 7B, FIG. 8A and FIG. 8B, after the probe pin was cleaned by the probe pin cleaning pad of Experimental Example 3 and the probe pin cleaning pad of Comparative Example 3, surfaces of the probe pin cleaning pads were evaluated. Among them, FIG. 7A and FIG. 8A have the same or similar image capturing conditions (for example, magnifying power, imaging light amount and/or imaging angle). In addition, FIG. 7A shows that puncturing was performed less than 300 times at the same position (that is, corresponding to one hole in FIG. 7A; there are three holes in FIG. 7A) on the probe pin cleaning pad of Comparative Example 3. FIG. 7B is an enlarged view corresponding to one of the holes in FIG. 7A. In addition, FIG. 8A shows that puncturing was performed more than 1500 times at the same position (that is, corresponding to one hole in FIG. 8A; there are three holes in FIG. 8A) on the probe pin cleaning pad of Experimental Example 3. FIG. 8B is an enlarged view corresponding to one of the holes in FIG. 8A.

As shown in FIG. 7A and FIG. 7B, after less than 300 times of puncturing, corresponding punctures were caused in the probe pin cleaning pad of Comparative Example 3. In comparison between FIG. 7A and FIG. 8A, it is clear that the probe pin cleaning pad of Comparative Example 3 had relatively deep punctures. That is, it is clear that relatively serious piercing damage (for example, a noticeable cross image in FIG. 7B) occurred in the probe pin cleaning pad of Comparative Example 3 after less than 300 times of puncturing. A cause of the piercing damage may be relatively poor resilience of the material due to the Young's modulus of the probe pin cleaning pad of Comparative Example 3 of less than 30 kg/cm². When the same image processing method was employed for determination (that is, the same image processing method was applied in FIG. 7B and FIG. 8B), as shown in FIG. 7B, the probe pin cleaning pad of Comparative Example 3 had corresponding holes of about 0.076 mm after less than 300 times of puncturing.

As shown in FIG. 8A and FIG. 8B, after more than 1500 times of puncturing, corresponding punctures might still be caused in the probe pin cleaning pad of Experimental Example 3. However, in comparison between FIG. 7A and FIG. 8A, it is clear that the probe pin cleaning pad of Experimental Example 3 had relatively unnoticeable or shallow punctures. That is, there might be less noticeable piercing damage (for example, FIG. 8B shows no noticeable cross image) in the probe pin cleaning pad of Experimental Example 3 after more than 1500 times of puncturing. A reason may be that the probe pin cleaning pad of Experimental Example 3 had a Young's modulus of greater than or equal to 30 kg/cm² (or further, greater than or equal to 50 kg/cm²), thus imparting relatively good resilience to the material. When the same image processing method was employed for determination (that is, the same image processing method was applied in FIG. 7B and FIG. 8B), as shown in FIG. 8B, the probe pin cleaning pad of Experimental Example 3 had corresponding holes of about 0.0683 mm after more than 1500 times of puncturing.

As shown in FIG. 7A, FIG. 7B, FIG. 8A, and FIG. 8B, compared to Comparative Example 3, the probe pin cleaning pad of Experimental Example 3 may have a relative large number of effective uses.

In summary, in the probe pin cleaning pad and the cleaning method for a probe pin by using the probe pin cleaning pad according to the disclosure, since the cleaning layer is adapted to adhere to a substance on the probe pin, the probe pin cleaning pad and the cleaning method for a probe pin are suitable for cleaning of probe pins and may reduce scratches on the probe pins.

What is claimed is:

1. A probe pin cleaning pad, comprising:
a release layer or composite material;
an adhesive layer, disposed on the release layer or composite material;
a substrate layer, disposed on the adhesive layer; and
a cleaning layer, disposed on the substrate layer.

2. The probe pin cleaning pad according to claim 1, wherein the release layer or composite material, the adhesive layer, the substrate layer, and the cleaning layer are sequentially stacked.

3. The probe pin cleaning pad according to claim 1, wherein the adhesive layer has a thickness of greater than or equal to 5 μm and less than or equal to 100 μm.

4. The probe pin cleaning pad according to claim 1, wherein the substrate layer has a thickness of greater than or equal to 6 μm and less than or equal to 300 μm.

5. The probe pin cleaning pad according to claim 1, wherein the cleaning layer has a Mohs hardness of less than 7, or has a Young's modulus of less than or equal to 100 kg/cm².

6. The probe pin cleaning pad according to claim 1, wherein the cleaning layer has a thickness of greater than or equal to 50 μm and less than or equal to 500 μm.

7. The probe pin cleaning pad according to claim 1, wherein a material of the cleaning layer comprises:
resin; and
organic powders.

8. The probe pin cleaning pad according to claim 7, wherein the resin comprises silicone, polyurethane, or a combination of the foregoing.

9. The probe pin cleaning pad according to claim 7, wherein the organic powders have a Mohs hardness of less than 7.

10. The probe pin cleaning pad according to claim 1, wherein a material of the cleaning layer comprises an organic material.

11. A cleaning method for a probe pin, comprising:
step 1: testing an electronic component by the probe pin; and
step 2: after step 1, cleaning the probe pin by the probe pin cleaning pad according to claim 1.

12. The cleaning method for a probe pin according to claim 11, wherein step 1 and step 2 are performed in-situ or on-line.
